(19) United States
(12) Patent Application Publication
(10) Pub. No.: US 2025/0318078 A1
(43) Pub. Date: Oct. 9, 2025

(54) METHOD AND APPARATUS FOR COMPLIANT DEVICE RECEIVER WITH HEAT TRANSFER ELEMENT

(71) Applicant: LTI Holdings, Inc., Pleasanton, CA (US)

(72) Inventor: Michael Beliveau, Belmont, NH (US)

(73) Assignee: LTI Holdings, Inc., Pleasanton, CA (US)

(21) Appl. No.: 19/097,969

(22) Filed: Apr. 2, 2025

Related U.S. Application Data
(60) Provisional application No. 63/573,549, filed on Apr. 3, 2024.

(51) Int. Cl. H05K 7/20

(52) U.S. Cl. CPC H05K 7/20272

(57) ABSTRACT

A heat transfer device includes a base that is configured to move relative to a support along a first direction and to receive a heat transfer fluid from the support via a fluid coupling. The fluid coupling is configured to expand and contract along the first direction to accommodate movement of the base relative to the support. The base may include a contact surface to engage and transfer heat with respect to a heat generating device, such as a device including optics modules requiring cooling. Heat received from the heat generating device may be transferred to the heat transfer fluid in a chamber of the base.

### RELATED APPLICATIONS

This application claims priority under 35 U.S.C. § 119 (e) to U.S. Provisional Application Ser. No. 63/573,549, filed Apr. 3, 2024, which is herein incorporated by reference in its entirety.

### FIELD OF INVENTION

A heat transfer device to compliantly receive a heat generating device for heat exchange, e.g., for cooling electronics of the heat generating device using a circulated flow of cooling fluid.

### BACKGROUND

With the development of electronic technology, heat dissipation requirements for computer processing devices, e.g., integrated circuits or chips, has increased, requiring ever higher efficiency liquid cooled heat exchange devices, e.g., liquid cooled heat sinks or liquid cold plates, to remove the heat generated by these devices.

### SUMMARY OF INVENTION

One type of device used to cool electronics or other heat generating devices is a liquid cold plate or liquid cooled heat exchanger that thermally couples a heat generating device (such as a computer processor, optical communications module, etc.). At least a portion of the heat exchanger may include a base that is thermally coupled to the heat generating device (e.g., physically contacts) and includes a chamber in which a thermal transfer fluid (e.g., cooling fluid) is circulated so that heat may be transferred from the base to the fluid and removed from the heat generating device. In some embodiments, the base may be resiliently biased to contact the heat generating device, e.g., by a spring or other resilient element. The chamber of the base may be fluidly coupled to a supply of heat transfer fluid by a base port on the base that is fluidly coupled to a supply port, e.g., on a support that physically supports the base. The fluid coupling may be configured to accommodate movement of the base relative to the support, e.g., movement of the base toward and away from the support. In some cases, the fluid coupling may be configured to extend and contract, e.g., increase in length and decrease in length, in a direction along which the base is movable relative to the support. This may permit the base to compliantly engage a heat generating device when the heat generating device is engaged with the base. For example, the base may be provided in a cavity configured to receive the heat generating device. When the heat generating device is inserted into the cavity, the base may compliantly move (e.g., under the bias of a spring) so the heat generating device can be received into the cavity and the base thermally coupled with the heat generating device.

In some embodiments, a heat transfer device includes a base having a surface configured to contact and receive heat from a heat generating component, such as an optical communications device or other data processing device. The base can have at least one base port configured to receive a heat transfer fluid, such as a cooling liquid, and a chamber fluidly coupled to the at least one base port, e.g., to receive the heat transfer fluid. In some cases, the chamber may function to hold transfer fluid that receives heat from the heat generating component. A support may be configured to physically support the base, with the base being movable relative to the support along a first direction, such as a direction perpendicular to a planar surface of the base that contacts the heat generating component to receive heat. The support may have at least one support port to provide the heat transfer fluid. A fluid coupling may be configured to fluidly couple the at least one base port with the at least one support port for movement of the heat transfer fluid, e.g., for transfer of relatively cool heat transfer fluid from the support to the base, and/or transfer of relatively warm heat transfer fluid from the base to the support. The fluid coupling may be configured to extend and contract along the first direction in response to movement of the base relative to the support along the first direction. For example, the base may be configured to compliantly engage with the heat generating device in the first direction, e.g., to accommodate differently sized device and/or thermal expansion/contraction. The fluid coupling may permit such motion along the first direction, e.g., while providing little or no resistance to such movement and continuing to provide a fluid connection for the heat transfer fluid.

In some cases, the fluid coupling may include a bellows configured to expand and contract along the first direction in response to movement of the base relative to the support. While a bellows is only one possible configuration for the fluid coupling, the bellows may permit movement along the first direction while maintaining a suitable fluid connection between the support and base.

In some embodiments, the at least one support port may include a first support port and the fluid coupling may include a first recess attached to the support at the first support port. The at least one base port may include a first base port and the fluid coupling may include a first sleeve attached to the base at the first base port and movably received in the first recess. For example, the first sleeve may move in the first recess in response to movement of the base relative to the support along the first direction. In some cases, the first recess and the first sleeve may be configured to sealingly engage in a range of movement of the first sleeve in the first recess, e.g., a leak proof fluid connection may be provided by the first recess and sleeve for movement of the base within a range of motion. In some cases, a seal such as an o-ring, x-ring, bellows or other may be provided between the first sleeve and the first recess, e.g., to provide sealing engagement while permitting movement of the sleeve relative to the recess. In some embodiments, the first base port is configured to provide the heat transfer fluid received from the first support port to the chamber, e.g., relatively cool heat transfer fluid may be delivered to the chamber to receive heat from the heat generating device. The at least one support port may include a second support port and the fluid coupling may include a second recess attached to the support at the second support port, and the at least one base port may include a second base port and the fluid coupling may include a second sleeve attached to the base at the second base port. The second sleeve may be movably received in the second recess, e.g., so the second recess and the second sleeve can sealingly engage in a range of movement of the second sleeve in the second recess. In some cases, the second base port may be configured to deliver the heat transfer fluid from the chamber to the second support port, e.g., so relatively warm heat transfer fluid can exit the chamber and flow to the support.

In some embodiments, a resilient element may be provided between the base and the support and may be configured to bias the base to move away from the support along the first direction. For example, a spring such as a leaf spring, coil spring, resilient material, etc., may be provided to bias the base to move away from the support. Such a resilient bias may permit the base to exert a compliant contacting force on the heat generating device, e.g., to aid in maintaining thermal engagement between the base and the device.

In some cases, the support includes a heat transfer fluid manifold configured to conduct a flow of the heat transfer fluid with respect to the at least one support port, e.g., the manifold may provide heat transfer fluid to one or more outlet support ports and receive heat transfer fluid from one or more inlet support ports. The base may similarly include one or more inlet base ports and one or more outlet base ports that are fluidly coupled to a corresponding support port by a fluid coupling.

In some embodiments, a housing may define a cavity in which the base is positioned, and the cavity may be configured to receive a heat generating device such that the base is in contact with the heat generating device for heat transfer with respect to the heat generating device. For example, the cavity may include an opening at a side of the housing so the heat generating device can be inserted into the cavity in a horizontal direction. In some cases, the base may be configured to move a vertical direction relative to the housing, i.e., the first direction may be along the vertical direction. In some cases, a resilient element such as a spring may bias the base into contact with the heat generating device. In some embodiments, the cavity may include a surface on a side of the cavity opposite the base and may be configured to support the heat generating device in the cavity. The resilient element may be configured to bias the base to move toward the surface, e.g., so the base can engage with the heat generating device in the cavity. In some cases, the cavity may have an opening to receive the heat generating device into the cavity by moving the heat generating device in a direction perpendicular to the first direction.

In some embodiments, a retainer may be configured to limit a range of movement of the base away from the support in the first direction. For example, a housing that includes the support may include a retainer to help keep the base from moving too far away from the support in the cavity.

In some cases, the base may include a contact plate configured to contact a heat generating device for heat transfer and a port plate including the at least one base port, e.g., the port and contact plates may define upper and lower surfaces of the base. The contact plate and port plate may define the chamber between the contact plate and the support plate.

In some cases, the fluid coupling may include a first portion attached to the base and a second portion attached to the support. The first and second portions may be configured to interact to permit movement of the base along the first direction and to resist movement of the base in directions perpendicular to the first direction. For example, in some embodiments, the first portion may include a protrusion or a recess and the second portion may include the other of a protrusion or a recess. The protrusion, e.g., a tubular element, may be configured to be received in the recess and may sealingly engage with the recess while permitting relative movement between the protrusion and recess. In some embodiments, a seal may be provided between the protrusion and the recess to provide sealing engagement for a range of movement of the protrusion relative to the recess.

In some cases, a fastener may be configured to engage the base and the support so as to limit movement of the base away from the support along the first direction and to limit movement of the base relative to the support in directions perpendicular to the first direction. For example, a screw or other threaded fastener may engage with the base and the support to provide limited movement of the base along the first direction. In some embodiments, a spring (such as a coil spring) may extend around the fastener and configured to bias the base to move away from the support along the first direction.

In some embodiments, a bearing may be configured to engage the base and the support to guide movement of the base relative to the support along the first direction and to limit movement of the base relative to the support in directions perpendicular to the first direction. For example, the bearing may include a journal bearing or other bearing to guide movement of the base relative to the support while providing little or no resistance to movement along the first direction. In some cases, the bearing may be positioned away from the at least one base port and the at least one support port; in some cases, the bearing may be positioned at the at least one base port and the at least one support port, e.g., portions of the fluid coupling may provide a bearing function.

These and other aspects of the invention will be appreciated from the following description and claims.

### BRIEF DESCRIPTION OF THE DRAWINGS

Aspects of the invention are described with reference to the following drawings in which numerals reference like elements, and wherein:

FIG. 1 is a perspective view of a housing configured to receive one or more heat generating devices for coupling with a heat exchanger in an illustrative embodiment;

FIG. 2 is a cross sectional view along the line 2-2 in FIG. 1;

FIG. 3 is a cross sectional view along the line 3-3 in FIG. 1;

FIG. 4 is a cross sectional view in an embodiment including a manifold having a protrusion is received in a recess on a heat exchanger base;

FIG. 5 is a close up view of a fluid coupling including a seal around a recess and complementary protrusion;

FIG. 6 is a cross sectional view of an embodiment including fluid coupling including a bellows element and a fastener coupling a heat exchanger base to a support;

FIG. 7 is a close up view of a fluid coupling including a bellows element as in FIG. 6; and

FIG. 8 is a cross sectional view of an embodiment including a bearing that guides movement of the base relative to the support.

### DETAILED DESCRIPTION

Aspects of the disclosure are not limited in application to the details of construction and the arrangement of components set forth in the following description or illustrated in the drawings. Other embodiments may be employed and aspects of the disclosure may be practiced or be carried out in various ways. Also, aspects and/or different features of embodiments described may be used alone or in any suitable combination with each other. Thus, the phraseology and terminology used herein is for the purpose of description and should not be regarded as limiting.

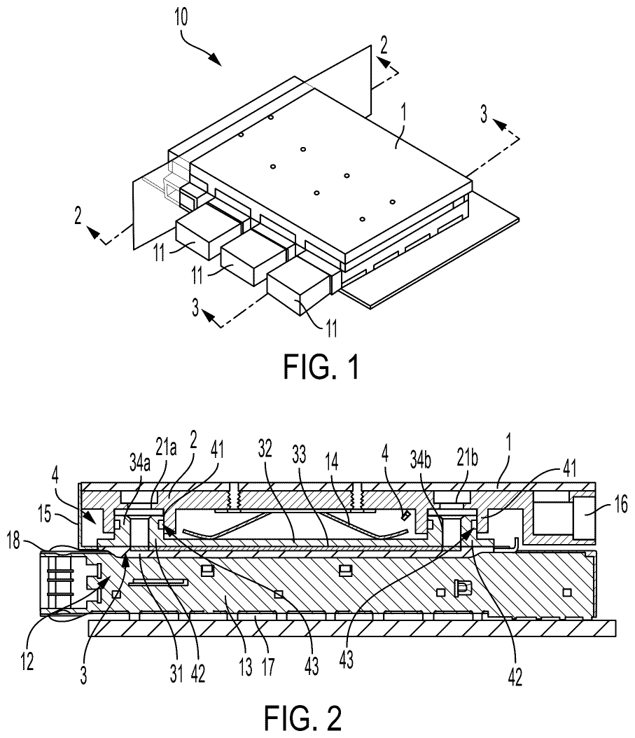

FIG. 1 shows a heat transfer device 10 in an illustrative embodiment. In some embodiments, the heat transfer device 10 includes a housing 1 having one or more cavities in which to receive a heat generating device 11, such as a device including computer processors, optical communications modules, or other components that generate heat (e.g., resulting from the use of electrical power to perform one or more functions). One or more heat generating devices 11 may be received by the housing 1 so that heat generated by the heat generating devices 11 can be transferred to a heat exchanger in the housing 1 and removed from the heat generating device 11.

FIG. 2 shows a cross sectional view of the heat transfer device 10 in an illustrative embodiment. In some cases, the housing 1 can include a cavity 13 to receive a heat generating device 11, e.g., a cavity 13 may be defined by a cage 18 having an opening 12 through which the heat generating device 11 may be inserted into the cavity 13. When received in the cavity 13, the heat generating device 11 may be thermally coupled to (e.g., in physical contact with) a base 3 to transfer heat between the heat generating device 11 and the base 3. The base 3 can be thermally coupled to the heat generating device 11 in any suitable way, such as by directly contacting the heat generating device 11 to a bottom surface of the base 3 or via an optional thermal interface component. In some cases, the base 3 may include a contact plate 31 configured to contact the heat generating device 11 and a port plate 32 coupled over the contact plate 31. The plates 31 and/or 32 which may be made of a thermally conductive material such as aluminum, copper or other suitable material. A chamber 33 may be defined between the contact plate 31 and the port plate 32 and may receive heat transfer fluid (e.g., a cooling liquid or other working fluid) via one or more base ports 34 that are in fluid communication with the chamber 33. The chamber 33 can be defined in different ways, such as by one or more grooves or recesses in the contact plate 31 and/or the port plate 32, standoffs or other spacer elements between the plates 31, 32, etc. Thus, heat from the heat generating device 11 can be received by the base 3 and transferred to the heat transfer fluid, which can carry the heat to a remote location for transfer to another device and/or to a surrounding environment. Cooled working fluid can be returned to the base 3 for repeated cooling cycles. The heat transfer fluid may operate in a single phase (e.g., always operate in liquid form) or in two or more phases (e.g., in vapor, liquid and/or mixed vapor and liquid form).

In some embodiments, the base 3 can be configured to compliantly engage with a heat generating device 11, e.g., the base 3 can be resiliently biased to contact the heat generating device 11 by a spring 14 or other resilient element. Compliant engagement of the base 3 with a heat generating device 11 can provide features such as permitting a heat generating device 11 to be inserted into the cavity 13 without the base 3 providing too much resistance to insertion of the heat generating device 11 and/or helping to maintain physical and thermal coupling of the base with the heat generating device 11. In some embodiments, the resilient element 14 can be a leaf spring, coil spring, elastomer material, pneumatic bladder, or other suitable component to provide a biasing force on the base 3. In some cases, the heat transfer device 10 may include a retainer 15 that helps limit movement of the base 3 in the cavity 13 under the bias of the spring 14. For example, the base 3 may have a rim or lip around its periphery that engages with the edges of an opening in the retainer 15 so that the base 3 is limited in the extent to which the base 3 can move into the cavity 13. In some cases, the base 3 may include a tapered or beveled edge, e.g., at or near the opening 12 or around its entire periphery. The tapered or beveled edge may help guide the heat generating device 11 into the cavity 13 and/or help prevent the base 3 from resisting entry of the heat generating device 11 into the cavity 13.

In some embodiments, the heat transfer device 10 may include a support 2 configured to physically support the base 3. For example, the retainer 15 may be attached to the support 2 so as to permit the support 2 to limit movement of the base 3 away from the support 2. In some embodiments, the resilient element 14 may be configured to exert force on the support 2 and the base 3 so as to bias the base 3 to move away from the support in a first direction, e.g., downwardly in FIG. 2. Thus, the support 2 may provide physical support to urge the base 3 into contact with the heat generating device 11. The support 2 may be attached to the housing 1 and/or a cage 18 where provided. In some cases, a surface 17 may be on a side of the cavity 13 opposite the base 3 and may support the heat generating device 11 in the cavity 13, e.g., to provide a counter force on the heat generating device 11 to help keep the heat generating device 11 in engagement with the base 3.

In some embodiments, the support 2 may include a manifold 16 or other suitable component to provide heat transfer fluid to the base 3. For example, the support 2 may include one or more support ports 21 to provide heat transfer fluid to one or more base ports 34 of the base 3. For example, the support 2 may include an inlet support port 21a to provide relatively cool heat transfer fluid to an inlet base port 34a of the base and an outlet support port 21b to receive relatively warm heat transfer fluid from an outlet base port 34b of the base 3. Thus, the manifold 16 may be configured to circulate heat transfer fluid through the chamber 33 of the base 3 to remove heat from the heat generating device 11. The manifold 16 may be configured in any suitable way, such as including pipes, conduits, flow channels, valves for controlling flow, etc. fluidly coupled to the support ports 21. In FIG. 2, the manifold 16 includes channels formed in a plate of the support 2.

In some embodiments, one or more fluid couplings 4 can fluidly couple a support port 21 to a base port 34, e.g., for exchange of heat transfer fluid between the ports 21, 34. A fluid coupling 4 can be configured to expand and contract along a first direction in which the base 3 is movable relative to the support 2, e.g., along a direction in which a spring 14 biases the base 3 to move into contact with a heat generating device 11. For example, a fluid coupling 4 can be configured to adjust in length along the first direction in response to movement of the base 3 relative to the support 4. This configuration can permit the base 3 to compliantly engage a heat generating device 11 while maintaining a fluid coupling for heat transfer fluid to the chamber 33 of the base 3. Moreover, such a configuration may provide a compact and reliable fluid coupling that facilitates the compliant nature of the base 3. For example, arrangements that require a conduit to bend or otherwise elastically deform to permit movement of a base relative to a support may impede movement of the base 3 and thereby impact its ability to compliantly engage with a heat generating device 11. In addition, such arrangements may cause the base 3 to move in other directions relative to the support 2 as the base 3 moves toward and away from the support 2, e.g., causing misalignment of the base 2. A fluid coupling 4 that adjusts in length in a direction along which the base 3 moves relative to the support 2 may provide little or no resistance to movement of the base 3, and thereby improve its compliance, and/or allow for proper alignment of the base 3 relative to the support 2 in its range of motion.

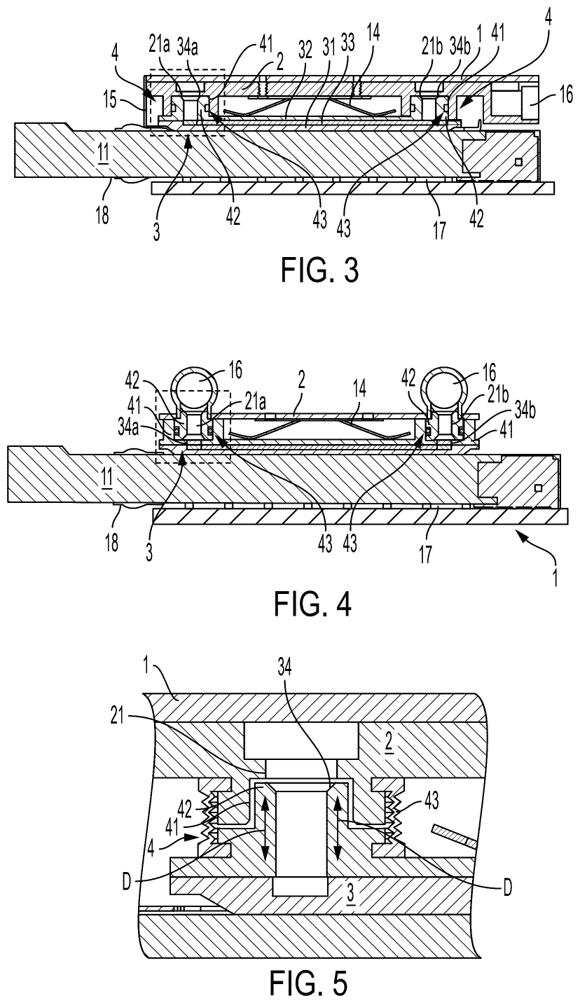

A fluid coupling 4 configured to adjust in length along a direction in which a base 3 moves relative to a support 2 can be arranged in different ways. For example, as shown in FIG. 2 a coupling 4 can include a recess 41 (e.g., attached to the support 2 at the support port 21) that receives a protrusion 42 (e.g., a sleeve attached to the base 3 at the base port 34). The protrusion 42 can be movable in the recess 41 along the first direction in a range of movement (e.g., equal to or greater than a range of movement of the base 3 relative to the support 2). In some cases, a seal 43 may be provided to provide a fluid tight coupling between the recess 41 and the protrusion 42 for a range of motion of the protrusion 42 relative to the recess 41, e.g., an o-ring, x-ring or other suitable component may be provided between the protrusion 42 and the recess 41. In some cases, the fluid coupling 4 may help guide movement of the base 3 relative to the support 2, e.g., the fluid coupling 4 may include a first portion (e.g., a protrusion 42) attached to the base 3 and a second portion (e.g., a recess 41) attached to the support 2, and the first and second portions may be configured to interact to permit movement of the base 3 along the first direction and to resist movement of the base 3 in directions perpendicular to the first direction. Thus, a fluid coupling 4 may help maintain alignment of the base 3 relative to the support 2 during movement of the base 3. As an example, FIG. 2 shows an embodiment in which the base 3 is moved away from the support 2 at its maximum possible distance, i.e., because the base 3 has contacted the retainer 15 which prevents any further movement of the base 3 away from the support 2. This is the state with no heat generating device 11 in the cavity 13. FIG. 3 shows the FIG. 2 embodiment with a heat generating device 11 inserted into the cavity 13. As can be seen, the base 3 has moved upwardly along the first direction toward the support 2 and against the bias of the spring 14. In response, the protrusion 42 of the fluid couplings 4 has been further moved into the corresponding recess 41, i.e., the fluid couplings 4 have been reduced in overall length to accommodate movement of the base 3 toward the support 2. In this state, the spring 14 continues to bias the base 3 into contact with the heat generating device 11, e.g., to provide physical and thermal coupling.

As noted above, fluid couplings 4 that are configured to adjust in length in response to movement of the base 3 relative to a support 2 can be configured in a variety of different ways. FIG. 4 shows an embodiment in which fluid couplings 4 include a recess 41 attached to the base 3 (e.g., the port plate 32) at a corresponding base port 34 and a protrusion 42 attached to the support 2 at a corresponding support port 21. In some embodiments, a portion of a coupling 4 (such as a protrusion 42 as in FIG. 4) can be attached to a conduit or other portion of the manifold 16, e.g., a pipe of a manifold 16 can include protrusions 41 or other coupling components attached to the pipe.

FIG. 5 shows yet another configuration for a fluid coupling 4. In FIG. 5, the fluid coupling 4 is configured similarly to that in FIG. 2 with a protrusion 42 attached to a base 3 at a corresponding base port 34 (e.g., so fluid can flow through the protrusion 42 to the base port 34) and a recess 41 attached to the support 2 at a corresponding support port 21 (e.g., so fluid can flow through the recess 41 to the support port 21). A seal 43 is provided around the protrusion 42 and recess 41 to provide a fluid seal between the support port 21 and the base port 34. For example, the seal 43 can be a bellows seal (e.g., made of a rubber, elastomer or other suitable material) configured to change length as the base 3 moves relative to the support 2. As with the FIG. 2 embodiment, the fluid coupling 4 may guide movement of the base 3 relative to the support 2, e.g., permitting movement along the first direction D but resisting movement in perpendicular directions. The configuration in FIG. 5 may also provide a stop feature, e.g., where portions of the recess 41 and protrusion 42 contact each other to limit movement of the base 3 toward the support 2.

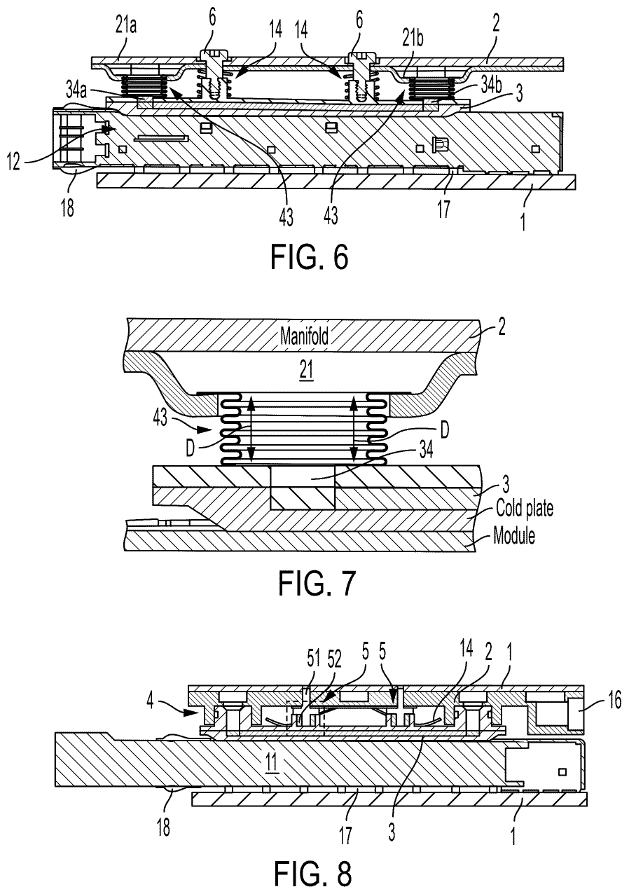

FIGS. 6 and 7 show another embodiment incorporating yet another coupling configuration. In some embodiments, a fluid coupling 4 can include only a bellows seal 43 that extends between the base 3 and the support 2 at a corresponding base port 34 and support port 21 to provide a fluid coupling between the ports 34, 21. As can be seen in FIG. 7, corresponding portions of the seal 43 may be attached to the support 2 and base 3 in any suitable way, such as by brazing, adhesive, clamping, etc. In some embodiments, the seal 43 may be formed of a metal material and/or a combination of metal and elastomer or other material. The seal 43 may be configured to adjust in length along a first direction D in response to movement of the base 3 relative to the support 2.

FIGS. 6 and 7 also illustrate another feature that may be incorporated into any embodiment, e.g., that a manifold 16 of a support 2 (or chamber 33 or other flow paths of a base 3) may be defined by stamped, bent or otherwise formed portions of a plate or other component. For example, the support 3 in FIGS. 6 and 7 includes top and bottom plates that are joined together and the bottom plate is stamped or otherwise formed to define a manifold or other flowpath for heat transfer fluid to be communicated to support ports 21. FIG. 6 also illustrates that movement of the base 3 relative to the support 2 may be guided, limited or otherwise controlled by components separate from a fluid coupling 4 and positioned away from any fluid port on the support 2 or base 3. For example, fasteners 6 may be engaged between the support 2 and the base 3 to limit a range of movement of the base 3 relative to the support, e.g., in the first direction D toward and away from the support 2 and/or in directions perpendicular to the first direction (e.g., in the plane of the base 3). In some cases, one or more fasteners 6 may be engaged with openings of the support 2 (e.g., that permit movement of the fasteners 6 in the vertical or first direction and limit movement in horizontal or directions perpendicular to the first direction) and secured to the base 3 (e.g., by threading into holes of the base 3). Springs 14 or other resilient elements may be positioned around the fasteners 6, e.g., coil springs may be positioned over the fasteners 6.

FIG. 8 shows another embodiment for guiding or otherwise controlling movement of a base 3 relative to a support 2. The FIG. 8 embodiment is similar to that in FIG. 2 but one or more bearings 5 are provided between the support 2 and base 3 to guide movement of the base 3. The bearings 5 may be linear bearings that permit movement of the base 3 while avoiding stick-slip motion problems. For example, the bearings 5 may include a protrusion element 51 (e.g., a pin or round shaft attached to the support 2) and a recess element 52 (e.g., a journal bearing or sleeve attached to the base 3). The bearings 5 may help guide movement of the base 3, e.g., resisting movement of the base 3 in horizontal or directions perpendicular to the first direction D, and thereby avoid any need for the fluid coupling 4 to provide such guidance for the base 3.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

The use of “including,” “comprising,” “having,” “containing,” “involving,” and/or variations thereof herein, is meant to encompass the items listed thereafter and equivalents thereof as well as additional items.

It should also be understood that, unless clearly indicated to the contrary, in any methods claimed herein that include more than one step or act, the order of the steps or acts of the method is not necessarily limited to the order in which the steps or acts of the method are recited.

While aspects of the invention have been described with reference to various illustrative embodiments, such aspects are not limited to the embodiments described. Thus, it is evident that many alternatives, modifications, and variations of the embodiments described will be apparent to those skilled in the art. Accordingly, embodiments as set forth herein are intended to be illustrative, not limiting. Various changes may be made without departing from the spirit of aspects of the invention.

1. A heat transfer device, comprising:
a base having a surface configured to contact and receive heat from a heat generating component, the base having at least one base port configured to receive a heat transfer fluid and a chamber fluidly coupled to the at least one base port;
a support configured to physically support the base, the base being movable relative to the support along a first direction, the support having at least one support port to provide the heat transfer fluid; and
a fluid coupling configured to fluidly couple the at least one base port with the at least one support port for movement of the heat transfer fluid, the fluid coupling configured to extend and contract along the first direction in response to movement of the base relative to the support along the first direction.

2. The heat transfer device of claim 1, wherein the fluid coupling includes a bellows configured to expand and contract along the first direction in response to movement of the base relative to the support.

3. The heat transfer device of claim 1, wherein the at least one support port includes a first support port and the fluid coupling includes a first recess attached to the support at the first support port, wherein the at least one base port includes a first base port and the fluid coupling includes a first sleeve attached to the base at the first base port and movably received in the first recess, and wherein the first recess and the first sleeve are configured to sealingly engage in a range of movement of the first sleeve in the first recess.

4. The heat transfer device of claim 3, further comprising a seal between the first sleeve and the first recess.

5. The heat transfer device of claim 3, wherein the first base port is configured to provide the heat transfer fluid received from the first support port to the chamber, wherein the at least one support port includes a second support port and the fluid coupling includes a second recess attached to the support at the second support port, wherein the at least one base port includes a second base port and the fluid coupling includes a second sleeve attached to the base at the second base port and movably received in the second recess, wherein the second recess and the second sleeve are configured to sealingly engage in a range of movement of the second sleeve in the second recess, and wherein the second base port is configured to deliver the heat transfer fluid from the chamber to the second support port.

6. The heat transfer device of claim 1, further comprising a resilient element between the base and the support configured to bias the base to move away from the support along the first direction.

7. The heat transfer device of claim 1, wherein the support includes a heat transfer fluid manifold configured to conduct a flow of the heat transfer fluid with respect to the at least one support port.

8. The heat transfer device of claim 1, further comprising a housing defining a cavity in which the base is positioned, the cavity configured to receive a heat generating device such that the base is in contact with the heat generating device for heat transfer with respect to the heat generating device.

9. The heat transfer device of claim 8, further comprising a resilient element to bias the base into contact with the heat generating device.

10. The heat transfer device of claim 9, wherein the cavity includes a surface on a side of the cavity opposite the base configured to support the heat generating device in the cavity and wherein the resilient element is configured to bias the base to move toward the surface.

11. The heat transfer device of claim 10, wherein the cavity has an opening to receive the heat generating device into the cavity by moving the heat generating device in a direction perpendicular to the first direction.

12. The heat transfer device of claim 1, further comprising a retainer configured to limit a range of movement of the base away from the support in the first direction.

13. The heat transfer device of claim 1, wherein the base includes a contact plate configured to contact a heat generating device for heat transfer and a port plate including the at least one base port, the contact plate and port plate defining the chamber between the contact plate and the support plate.

14. The heat transfer device of claim 1, wherein the fluid coupling includes a first portion attached to the base and a second portion attached to the support, the first and second portions configured to interact to permit movement of the base along the first direction and to resist movement of the base in directions perpendicular to the first direction.

15. The heat transfer device of claim 14, wherein the first portion includes a protrusion or a recess and the second portion includes the other of a protrusion or a recess, the protrusion configured to be received in the recess.

16. The heat transfer device of claim 15, further comprising a seal between the protrusion and the recess to provide sealing engagement for a range of movement of the protrusion relative to the recess.

17. The heat transfer device of claim 1, further comprising a fastener configured to engage the base and the support so as to limit movement of the base away from the support along the first direction and to limit movement of the base relative to the support in directions perpendicular to the first direction.

18. The heat transfer device of claim 17, further comprising a spring extending around the fastener and configured to bias the base to move away from the support along the first direction.

19. The heat transfer device of claim 1, further comprising a bearing configured to engage the base and the support so as to guide movement of the base relative to the support along the first direction and to limit movement of the base relative to the support in directions perpendicular to the first direction.

20. The heat transfer device of claim 19, wherein the bearing is positioned away from the at least one base port and the at least one support port.
